(19) United States
(12) Patent Application Publication
(10) Pub. No.: US 2026/0178009 A1
(43) Pub. Date: Jun. 25, 2026

(54) INTEGRATED FRICTION WELDING AND THREE-DIMENSIONAL PRINTING SYSTEM

(71) Applicant: INTERNATIONAL BUSINESS MACHINES CORPORATION, Armonk, NY (US)

(72) Inventors: Martin G. Keen, Cary, NC (US); Carolina Garcia Delgado, Zapopan (MX); Sarbajit Kumar Rakshit, Kolkata (IN); NEIL DELIMA, Scarborough (CA)

(21) Appl. No.: 18/999,103

(22) Filed: Dec. 23, 2024

(51) Int. Cl. G05B 19/4099; G06F 30/27

(52) U.S. Cl. CPC G05B 19/4099; G06F 30/27; G05B 2219/39132; G05B 2219/49007

(57) ABSTRACT

Systems and methods are provided for an integrated friction welding and three-dimensional printing system. An initial printing plan that slices the target 3D objects into parallel segmented objects can be generated with an artificial intelligence enabled control system (AECS). A 3D printing process and a friction welding process for the initial printing plan can be simulated with the AECS for the parallel segmented objects to generate a synchronized printing plan. The parallel segmented objects can be printed based on the synchronized printing plan by generating g-codes for a 3D printer. The parallel segmented objects can be welded together based on the synchronized printing plan by generating instruction commands for a robotic arm.

### BACKGROUND

The present invention generally relates to three-dimensional (3D) printing, and more particularly to an integrated friction welding and three-dimensional printing system.

Three dimensional (3D) printing, also known as additive manufacturing, has revolutionized the way objects are designed and created. It allows for the fabrication of complex geometries layer by layer, from digital blueprints.

Friction welding is a solid-state welding process that joins two materials through the generation of heat caused by friction between the two components. The basic principle is to rub or “weld” two materials together by applying pressure and causing the generation of heat at their interface.

### SUMMARY

In accordance with an embodiment of the present invention, a computer system is provided, including, a processor set, one or more computer-readable storage media, and program instructions stored on the one or more computer-readable storage media to cause the processor set to perform operations having generating, with an artificial intelligence enabled control system (AECS), an initial printing plan that slices a target 3D object into parallel segmented objects, simulating, with the AECS, a 3D printing process and a friction welding process for the initial printing plan of the parallel segmented objects to generate a synchronized printing plan, printing the parallel segmented objects based on the synchronized printing plan by generating g-codes for a 3D printer, and welding the parallel segmented objects based on the synchronized printing plan by generating instruction commands for a robotic arm.

In accordance with another embodiment of the present invention, a computer-implemented method is provided for synchronized three-dimensional (3D) printing and friction welding of objects, including generating, with an artificial intelligence (AI)-enabled control system (AECS), an initial printing plan that slices a target 3D object into parallel segmented objects, simulating, with the AECS, a 3D printing process and a friction welding process for the initial printing plan of the parallel segmented objects to generate a synchronized printing plan, printing the parallel segmented objects based on the synchronized printing plan by generating g-codes for a 3D printer, and welding the parallel segmented objects based on the synchronized printing plan by generating instruction commands for a robotic arm.

In accordance with yet another embodiment of the present invention, computer program product is provided for synchronized three-dimensional (3D) printing and friction welding of objects, the computer program product including one or more computer-readable storage media, and program instructions stored on the one or more computer-readable storage media to perform operations having generating, with an AI-enabled control system (AECS), an initial printing plan that slices a target 3D object into parallel segmented objects, simulating, with the AECS, a 3D printing process and a friction welding process for the initial printing plan of the parallel segmented objects to generate a synchronized printing plan, printing the parallel segmented objects based on the synchronized printing plan by generating g-codes for a 3D printer, and welding the parallel segmented objects based on the synchronized printing plan by generating instruction commands for a robotic arm.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a block diagram showing a high-level overview of an integrated friction welding and 3D printing system, in accordance with an embodiment of the present invention;

FIG. 2 is a flow diagram showing a computer-implemented method of an integrated friction welding and 3D printing process, in accordance with an embodiment of the present invention;

FIG. 3 is a block diagram showing an integrated friction welding and 3D printing system, in accordance with an embodiment of the present invention;

FIG. 4 is a block diagram showing a system that performs synchronized 3D printing and friction welding, in accordance with an embodiment of the present invention; and

FIG. 5 is a block diagram showing a method of synchronized 3D printing and friction welding, in accordance with an embodiment of the present invention.

### DETAILED DESCRIPTION

In accordance with embodiments of the present invention, systems and methods are provided for an integrated friction welding and three-dimensional (3D) printing system. The present embodiments can synchronize 3D printing and friction welding to generate large complex objects in an effective and efficient manner.

With the present embodiments, an initial printing plan that slices the target 3D objects into parallel segmented objects can be generated with an artificial intelligence (AI) enabled control system (AECS). A 3D printing process and a friction welding process for the initial printing plan can be simulated with the AECS for the parallel segmented objects to generate a synchronized printing plan. The parallel segmented objects can be printed based on the synchronized printing plan by generating g-codes for a 3D printer. The parallel segmented objects can be welded together based on the synchronized printing plan by generating instruction commands for a robotic arm.

In manufacturing, the creation of large and complex structures through 3D printing faces a few roadblocks. Traditional 3D printers have a limited area in which they can operate, which restricts the size of the objects they can create. Additionally, the intricacy of designs and the properties of materials used can further complicate the process. This creates a bottleneck for industries that rely on the rapid and precise assembly of large-scale components, from the detailed parts needed in aerospace to the sturdy components required in automotive manufacturing. Further, current methods struggle with seamlessly combining printed segments into larger structures without visible seams or weak points.

To address at least the following issues described herein, the present embodiments can synchronize 3D printing and friction welding to generate large complex objects in an effective and efficient manner. By doing so, the present embodiments can print large 3D objects in parallel that are subdivided by segments which can be assembled effectively with welding.

Exemplary applications/uses to which the present invention can be applied include, but are not limited to: manufacturing of custom-made consumer products, construction of buildings, large structures, houses, etc.

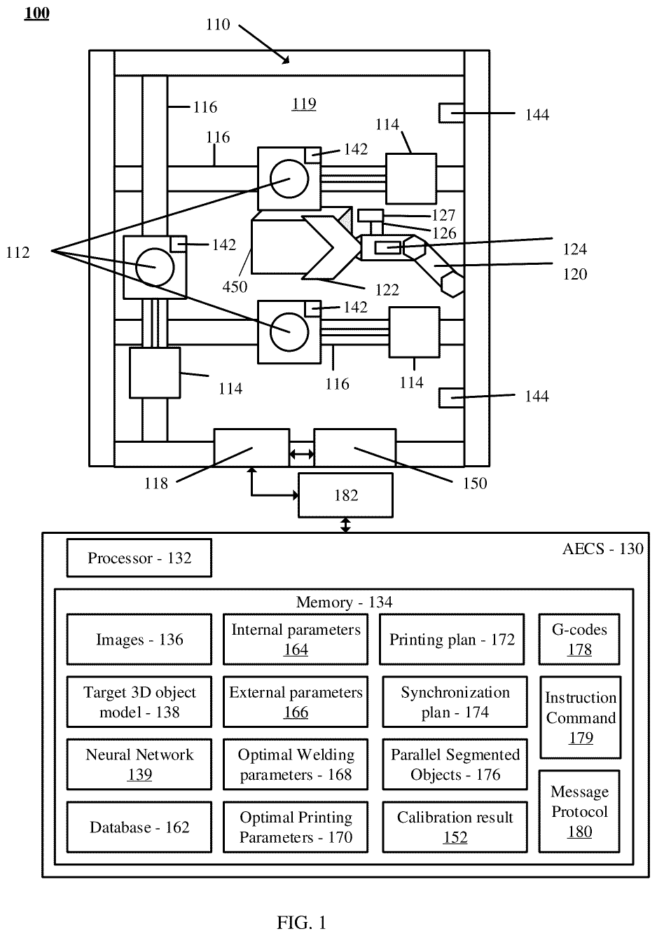

Referring now to the drawings in which like numerals represent the same or similar elements and initially to FIG. 1, a flow diagram showing a high-level overview of an integrated friction welding and 3D printing system, in accordance with an embodiment of the present invention.

With the present embodiments, an initial printing plan that slices the target 3D objects into parallel segmented objects can be generated with an AI-enabled control system (AECS). A 3D printing process and a friction welding process for the initial printing plan can be simulated with the AECS for the parallel segmented objects to generate a synchronized printing plan. The parallel segmented objects can be printed based on the synchronized printing plan by generating g-codes for a 3D printer. The parallel segmented objects can be welded together based on the synchronized printing plan by generating instruction commands for a robotic arm.

The system 100 can include a three-dimensional (3D) printer 110, a robotic arm 120, an AI-enabled control system (AECS) 130, a network of sensors 140, and a calibration system 150.

The 3D printer 110 is the core of the system which is capable of 3D printing large complex objects with high precision. The 3D printer 110 can include a 3D digital model slicing system 118 which can generate, receive, and perform g-code 178 that accounts for the parallel segmented objects 176. The g-code 178 can include commands for pausing the 3D printer 110 and instructing the robotic arm 120 when to perform friction welding. The parallel segmented objects 176 can include the segmented portions of the target 3D object based on the analysis of the AECS 130. The 3D printer 110 can include one or more material reservoir 114 that can hold the printing material for 3D printing. The material reservoirs 114 can be synchronized to produce the same material depending on the printing plan 172. In another embodiment, the material reservoirs 114 can produce different materials depending on the printing plan 172.

The 3D printer 110 can include nozzles 112 that produce processed material to form the parallel segmented objects 176 based on the g-code 178. The nozzles 112 can be attached to mounting arms 116. The nozzles 112 can print simultaneously based on the printing plan 172 and the synchronization plan 174. The mounting arms 116 can move laterally, horizontally, extend, or contract, etc., depending on the g-code 178. The 3D printer 110 can include a assembly area 119 where the parallel segmented objects 176 can be 3D printed and friction welded.

The robotic arm 120 can friction weld segmented 3D printing parts. The robotic arm 120 is compatible with the 3D printer 110. The robotic arm 120 can handle the weight and size of the parallel segmented objects 176 and can perform rotational movement for friction welding. The robotic arm 120 can include a customized gripper 122 for securely holding the 3D printed parts during friction welding, and can create rotational movement. The customized gripper 122 can adapt to the shape of the parallel segmented objects 176 to increase grip and to secure the parallel segmented objects 176 while friction welding. The customized gripper 122 can include at least two gripping appendages connected to a joint that can interact with the parallel segmented objects 176.

The robotic arm 120 can include a friction welding component 126 that performs friction welding on the parallel segmented objects 176. The friction welding component 126 can include a rotating component 127 that can be pressed on the parallel segmented objects 176 that generates friction and heat due to the resistance to movement. The heat generated by friction softens the materials at their interface. The heating occurs without melting the materials of the parallel segmented objects 176 and that they remain in a solid state during the process.

After a sufficient amount of heating, the rotating component 127 is quickly stopped while pressure is maintained. To determine the sufficient amount of heating, the speed and number of rotations can be determined by the AECS 130 based on the material used. In another embodiment, the speed and number of rotations can be part of the specification of the target 3D object model 138. In another embodiment, ultrasonic sensors can be employed to detect the material used and to determine the sufficient heat to be produced by the rotating component 127. In another embodiment, visual recognition models (e.g., convolutional neural networks, semantic segmentation models, vision transformers, etc.) can be employed to detect the material used and to determine the sufficient heat to be produced by the rotating component. The heat, pressure, and relative motion of the components cause the softened material to bond together and form a solid joint. Axial pressure may also be applied to ensure a strong bond. After the joint is formed, it is allowed to cool down and solidify. This cooling process solidifies the bond between the materials.

In another embodiment, the robotic arm 120 can grab and linearly oscillate one parallel segmented object 176 relative to another parallel segmented object 176 while under a compressive force. In another embodiment, the robotic arm 120 can grab and rotationally oscillate one parallel segmented object 176 relative to another parallel segmented object 176 while under a compressive force. The friction between the oscillating surfaces of the parallel segmented objects 176 produces heat which causes the interface material to soften and mechanically mix. In both embodiments, during the welding process, the parallel segmented objects 176 have portions that can shorten in the direction of the compressive force, forming a flash. During the burn-off, interface contaminants such as oxides and foreign particles are expelled from the flash. After this expelling the contaminants, the bonding process of the materials of the parallel segmented objects occurs.

The robotic arm 120 can reach the assembly area 119 of the 3D printer 110, and the object can be gripped to create movement (e.g., rotational, lateral, or through rotating component 127, etc. ,) for friction welding. The robotic arm 120 can include a local calibration system 124 that can calibrate and align the 3D printer 110 and robotic arm to ensure precise coordination during printing and friction welding. The robotic arm 120 can also identify the parallel segmented objects 176 that are printed separately in parallel and can consider how to friction weld the parallel segmented objects 176 together through the local calibration system 124. The robotic arm 120 can control the type of movement (e.g., rotation, lateral movement), the direction of movement (e.g., clockwise or anti-clockwise in case of rotation) and the speed of the movement to achieve the desired assembly results through the local calibration system. In an embodiment, there can be multiple robotic arms 120 that can simultaneously friction weld multiple parallel segmentation objects 176 together.

The local calibration system 124 of the robotic arm 120 can include a number of alignment sensors such as gyroscopes, photoelectric sensors, cameras, neural network, etc., to calibrate and align the 3D printer 110 and robotic arm 120. The local calibration system 124 can communicate with the AECS 130 to receive and send data to ensure precise coordination and synchronization with the 3D printer 110 to ensure an effective and efficient printing and friction welding process of the target 3D object. Further the local calibration system 124 can control the amount of force to be applied so that the objects adhere at the welding contact surface.

The AI-enabled control system (AECS) 130 can include machine learning capabilities for analyzing, segmenting, optimizing, and controlling the 3D printing process and the friction welding process. The AECS 130 can include one or more processors 132 that is operatively coupled with a memory device 134 to perform the operations for the AECS 130 as described herein.

The AECS 130 can generate a printing plan 172 that can slice the target 3D model into the parallel segmented objects 176. The AECS 130 can ensure that each part is printed with appropriate alignment features to aid in assembly with friction welding. The AECS 130 can handle the coordination between the 3D printer 110 and the robotic arm 120 through the synchronization plan 174. The AECS 130 can generate instruction commands 179 for the robotic arm 120 to grip one of the parallel segmented objects 176 once they are printed. The AECS 130 can generate a synchronization plan 174 that can generate sequences of actions for the 3D printer 110 and the robotic arm 120 which can pause the 3D printer 110 at the optimal moment, allowing the robotic arm 120 to bring the gripped part to the assembly area 119.

The AECS 130 can include a neural network 139 that can learn historical data, such as training datasets, past target 3D models, and past identified segmentation points and assembly points, that can be obtained from the database 162 and learn to recognize patterns relevant to the 3D printing process and the friction welding process. The neural network 139 can include point cloud-based models such as PointNet, Mesh-based models such as graph neural networks, convolutional neural networks, transformer-based models, etc.

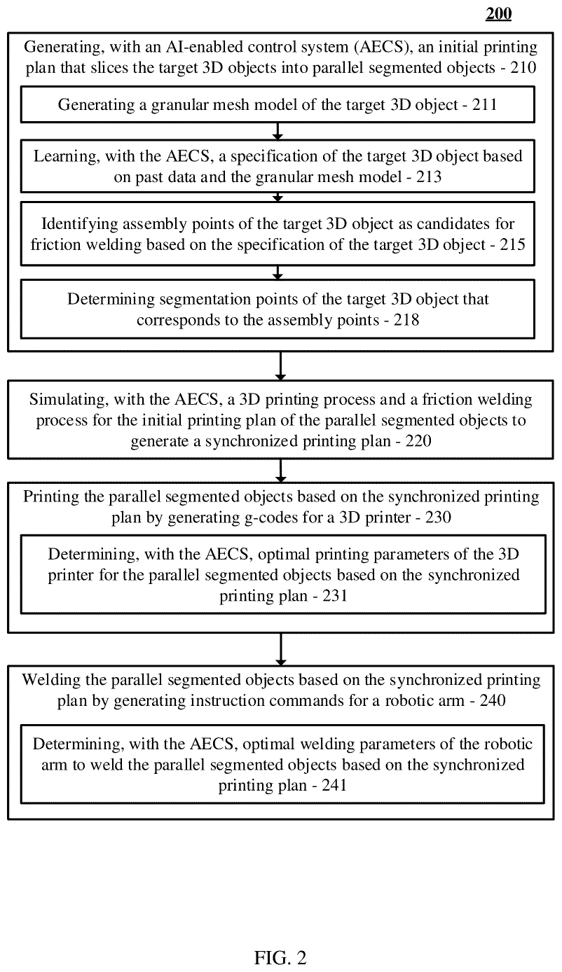

The AECS 130 can learn the optimal printing parameters 170 based on the collected data by the network of sensors 140 regarding the 3D printer 110 including internal parameters 164 and external parameters 166 such as nozzle speed, material temperature, microstructure of the target 3D object, etc., by employing classification machine learning models such as random forest. The AECS 130 can learn the optimal welding parameters 168 based on the collected data by the network of sensors 140 regarding the robotic arm 120 that are included in the internal parameters 164 and external parameters 166 such as orientation, assembly point surface roughness level, temperature, etc., by employing classification machine learning models such as random forest. These methods are shown in more detail in FIG. 2.

The network of sensors 140 can include external sensors 144 and embedded sensors 142 that can gather data related to the 3D printing process, the friction welding process, the quality of the printed parts, and the quality of the welded parts such as images 136 that can capture the surface geometry of the target 3D object. The network of sensors 140 can include external sensors 144 that are high-fidelity sensors for environmental variables such as anemometers for wind speed, hygrometers for humidity, and thermometers for temperature. These sensors can be integrated into the hardware of 3D printer 110. Additionally, internal parameters 164 such as nozzle speed, deposition rate, and layer height can be monitored using the embedded sensors 142. The data collected can be stored in database 162. These data points can be preprocessed and streamed using a message protocol 180 such as the message queuing telemetry transport (MQTT) channel.

The calibration system 150 can calibrate the assembled 3D object and identify deviations, deformations or excess materials. The calibration system 150 can perform quality control checks to identify any issues with the assembly. These data can be used for further refinement, correction, and training of the AECS 130. The calibration system 150 can communicate with the AECS 130 to generate a calibration result 152.

The calibration result 152 can include adjustments in the x, y, and z axes to ensure that the quality level of assembly is correct. Additionally, the calibration result 152 can include issues that were detected visually and solutions for such issues by comparing an expected quality level from the specification of the target 3D object and the images taken by the external sensors such as stringing, layer separation, gaps, etc.

The system 100 can include a motion control system 182 that can synchronize the actions of the robotic arm 120 and the 3D printer 110 based on a synchronization plan 174. The motion control system 182 can include a motion controller, amplifier, primer mover, feedback sensors, etc. The motion control system 182 can communicate with the 3D printer 110, the robotic arm 120 and the AECS 130.

Referring now to FIG. 2, a block diagram showing a computer-implemented method of an integrated friction welding and 3D printing process, in accordance with an embodiment of the present invention.

In block 210, an initial printing plan that slices a target 3D object into parallel segmented objects can be generated with an AI-enabled control system (AECS).

To analyze the target 3D object, the present embodiments can segment the target 3D object into multiple parts that can be later assembled with friction welding. The present embodiments can receive a target 3D object model 138 of the target 3D object. In another embodiment, the present embodiments can capture a target 3D object model 138 of the target 3D object by using the network of sensors 140.

In block 211, with the 3D digital model collected, the present embodiments can create a granular mesh model of the target 3D object through the AECS 130. A scanner which is part of the external sensors 144 can collect images 136 that can capture the surface geometry of the object. The granular mesh model can be generated by refining the mesh density of the surface geometry of the target 3D object.

In block 213, the AECS 130 can process and learn a specification of the target 3D object based on past data and the granular mesh model. The specification of the target 3D object can include the shape constraints such as surface curvature, edges, corners, connected parts (e.g., limbs of an 3D model of an animal), overhangs, structural stability, etc. The AECS 130 can use datasets to learn the specification of the target 3D object. The AECS 130 can utilize existing datasets such as datasets with part annotations such as PartNet to build its custom dataset. To build its custom dataset, the AECS 130 can determine the viability of the segmented parts and its connection points from the existing dataset for segmentation and friction welding. If the connection points and its corresponding segmented parts are viable for segmentation and friction welding, then it can be stored as potential ground truth data for segmentation points and assembly points.

The AECS 130 can consider the assembly area 119 when generating the printing plan and ensure that the parallel segmented objects can be printed and friction welded in a synchronized fashion.

In block 215, the AECS can identify assembly points of the target 3D object based on the learned specification of the target 3D objects. The assembly points are portions of the target 3D object that can become candidates for friction welding based on the shape constraints of the parallel segmented objects. The shape constraints can include the geometry, the dimension, surface roughness, etc. of the parallel segmented objects will be considered for friction welding. The AECS 130 will analyze the target 3D object to generate a target 3D object model 138 to identify areas where friction welding is both feasible based on the shape constraints, load capacity, material compatibility, etc. In another embodiment, the AECS 130 can process a preconfigured specification of the target 3D object with predefined assembly points and segmentation points that were preselected by a decision making entity. The AECS 130 can be trained to identify the assembly points based on past data having a number of issues found less than a predefined issue threshold (e.g., zero, one). In another embodiment, the AECS 130 can communicate with other 3D printers to obtain ground truth assembly points.

In block 218, based on the learned specification of the target 3D object, the AECS 130 can also determine segmentations points which are portions of the target 3D object that can be sliced to divide the 3D model into separate segments by using the 3D printer 110. These segmentation points should correspond to the identified assembly points. The segmentation points can be extended from the assembly points to divide the target 3D object model 138 using the 3D digital model slicing system 118. To identify the segmentation points, the structural stress points, material properties and geometric features (e.g., natural contours, planes, etc.) of the target 3D object model 138 are analyzed.

The AECS 130 can be trained to identify the segmentation points from past data that includes successful (e.g., zero issues found) prints having parallel segmented objects 176. In another embodiment, the AECS 130 can be trained to identify the segmentation points from simulation data that includes stress analysis and structural integrity of segmentation approaches for the target 3D object model 138. In another embodiment, the AECS 130 can be trained to identify the segmentation points from predefined segmentation points from computer-aided design (CAD) libraries. In another embodiment, the past data can be provided by experts.

Based on the segmentation points and the assembly points of the target 3D object, the AECS 130 can generate an initial printing plan 172 that includes the sequence for 3D printing the identified parallel segmented objects 176 and for friction welding the parallel segmented objects 176 in a synchronized manner. This sequence of actions can be identified based on the relative position of the parallel segmentation objects 176 to an identified starting point. In an embodiment, the 3D printing and friction welding can be performed in parallel based on the area that would be used from the 3D assembly area 119 (e.g., if there is ample space for both the 3D printing and the friction welding process).

The AECS 130 can identify additional deposit material on the segmented portion and surface roughness level of the segmented portion to execute friction welding. The AECS 130 can consider the properties of the material and whether they are compatible with friction welding. Some materials can weld more effectively than others. The AECS 130 can consider the material properties and the friction welding process. The AECS 130 can calculate and incorporate an allowance for additional material deposition on the parallel segmented objects 176 to account for material loss during welding. This ensures that the assembled object 450 can meet the desired dimensional specifications, learned specifications, or a predefined specification.

The AECS 130 can be built based on historically analysis of the friction welding based assembling, quality assessment, and will identify the allowance of additional material deposit.

The AECS 130 can continuously learn and adapt based on data collected, including feedback from the network of sensors 140, during the printing and assembly process. The AECS 130 can retain previously learned knowledge through elastic weight consolidation (EWC).

Referring now to block 220, a 3D printing process and a friction welding process for the initial printing plan of the parallel segmented objects can be simulated with the AECS to generate a synchronization plan, in accordance with an embodiment of the present invention.

Once the 3D object is segmented, the AECS 130 can simulate the 3D printing in parallel and friction welding of the segmented parts. During simulation, the AECS 130 can consider the 3D printing and robotic arm 120 capability for friction welding. The AECS 130 can generate simulations of different orientations of the 3D printing and friction welding processes to determine the optimal orientations that enables the 3D printing and friction welding process effective and efficient. To determine the optimal orientation, the printing parameters and the welding parameters will be subjected to an optimality threshold. The optimality threshold can be predefined and can range from zero to one. For example, the optimality threshold can be 0.9.

With various orientations of the 3D object, the AECS 130 can simulate the synchronization of the 3D printing and friction welding can be performed to determine their order of actions. Depending on the printing plan 172, the 3D printing and friction welding can be sequential or done in parallel. Based on the simulated synchronization, a synchronization plan 174 can be created. During this simulation, the AECS 130 can adjust the segments to be as independent as possible, minimizing the need for support structures and ensuring that they can be printed in parallel.

Based on the segmentation and the simulation of the printing and friction welding, the AECS 130 can plan the sequence for printing the different segmented portions. Depending on the resulting synchronization plan 174, some segments may be printed and friction welded sequentially, while others can be printed and friction welded simultaneously.

Referring now to block 230, the parallel segmented objects can be printed based on the synchronized printing plan by generating g-codes for a 3D, in accordance with an embodiment of the present invention.

For each segment, the AECS 130 can identify and set the optimal printing parameters 170, including layer height, print speed, and infill density. The AECS 130 can adjust these parameters to suit the specific requirements of each segment, as they can vary based on size and complexity. To identify the optimal printing parameters 170, a quality level can be determined on the currently printed object. The quality level can include the occurrence of gaps, blobs, spots, etc. on the surface of the currently printed object. The printing parameters that minimize the occurrence of gaps, blobs, spots, etc. on the surface of the currently printed object compared a predefined optimal printing threshold (e.g., up to 5% occurrence, etc.) can be determined as the optimal printing parameters 170. The printing parameters can be obtained from a simulation or through past data. Based on the optimal printing parameters 170 and the synchronization plan 174, the AECS 130 can generate g-codes 178 for printing the parallel segmented objects 176 using a 3D printer 110. The AECS 130 can generate multiple g-codes 178 for the multiple nozzles 112 to print the parallel segmented objects 176 in parallel.

Referring now to block 240, the parallel segmented objects can be welded based on the synchronized printing plan by generating instruction commands for a robotic arm, in accordance with an embodiment of the present invention.

The AECS 130 can also determine the optimal welding parameters 168. The optimal welding parameters 168 can include the optimal level of surface roughness, allowance for additional material deposition, optimal orientation of friction welding, geometry and dimensional specification of the welding points. The optimal level of surface roughness on the contact surfaces of the 3D object where friction welding can be determined based on material properties, rotational speed created by the rotational component 127, and other relevant factors. To identify the optimal welding parameters 168, a quality level can be determined on the currently welded object. The quality level can include the occurrence of gaps, blobs, spots, etc. on the surface of the currently welded object. The welding parameters that minimize the occurrence of gaps, blobs, spots, etc. on the surface of the currently welded object compared a predefined optimal welding threshold (e.g., up to 5% occurrence, etc.) can be determined as the optimal welding parameters 168. The welding parameters can be obtained from a simulation or through past data.

The AECS 130 can incorporate an allowance for additional material deposition with appropriate thickness on each segmented 3D object to ensure that the geometry and dimensional specifications remain unaffected. The AECS 130 can optimize the orientation and sequence of printing and welding. Based on the optimal welding parameters 168 and the synchronization plan 174, instruction commands 179 can be generated by the AECS 130 for friction welding of the parallel segmented objects 176 using the robotic arm 120. The instruction commands 179 for the robotic arm 120 can allow the friction module component 126 of the robotic arm 120 to perform the friction welding process as described herein.

Thus, the present embodiments can synchronize 3D printing and friction welding to generate large complex objects in an effective and efficient manner. By doing so, the present embodiments can print large 3D objects in parallel that are subdivided by segments which can be assembled effectively with welding.

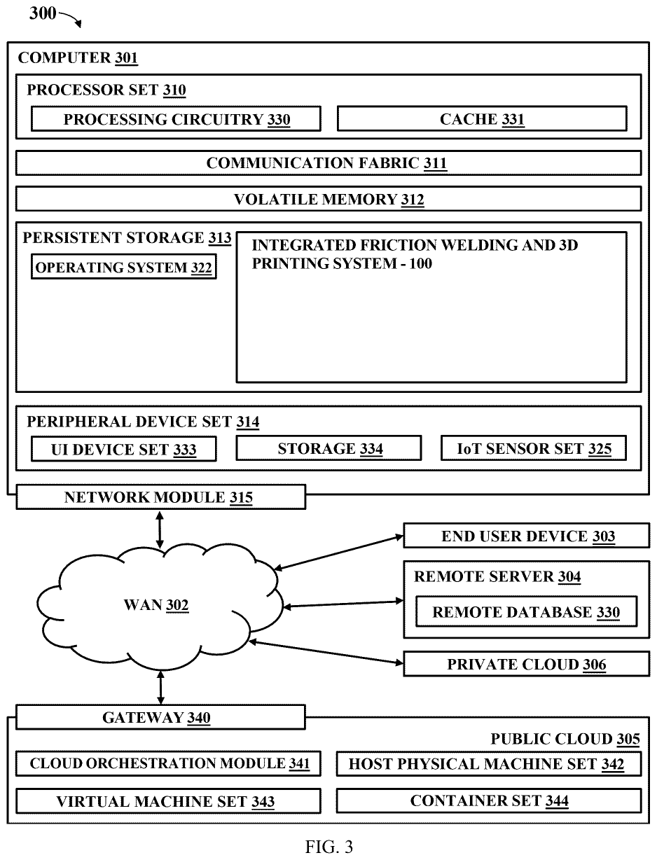

Referring now to FIG. 3, a block diagram showing an integrated friction welding and 3D printing system, in accordance with an embodiment of the present invention.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 300 contains an example of an environment for the execution of at least some of the computer code involved in performing the inventive methods, such as an integrated friction welding and three-dimensional printing system 100. In addition to block 100, computing environment 300 includes, for example, computer 301, wide area network (WAN) 302, end user device (EUD) 303, remote server 304, public cloud 305, and private cloud 306. In this embodiment, computer 301 includes processor set 310 (including processing circuitry 320 and cache 321), communication fabric 311, volatile memory 312, persistent storage 313 (including operating system 322 and block 100, as identified above), peripheral device set 314 (including user interface (UI) device set 323, storage 324, and Internet of Things (IoT) sensor set 325), and network module 315. Remote server 304 includes remote database 330. Public cloud 305 includes gateway 340, cloud orchestration module 341, host physical machine set 342, virtual machine set 343, and container set 344.

COMPUTER 301 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 330. As is well understood in the art of computer technology, and depending upon the technology, performance of a computer-implemented method may be distributed among multiple computers and/or between multiple locations. On the other hand, in this presentation of computing environment 300, detailed discussion is focused on a single computer, specifically computer 301, to keep the presentation as simple as possible.

Computer 301 may be located in a cloud, even though it is not shown in a cloud in FIG. 3. On the other hand, computer 301 is not required to be in a cloud except to any extent as may be affirmatively indicated.

PROCESSOR SET 310 includes one, or more, computer processors of any type now known or to be developed in the future. Processing circuitry 320 may be distributed over multiple packages, for example, multiple, coordinated integrated circuit chips. Processing circuitry 320 may implement multiple processor threads and/or multiple processor cores. Cache 321 is memory that is located in the processor chip package(s) and is typically used for data or code that should be available for rapid access by the threads or cores running on processor set 310. Cache memories are typically organized into multiple levels depending upon relative proximity to the processing circuitry. Alternatively, some, or all, of the cache for the processor set may be located “off chip.” In some computing environments, processor set 310 may be designed for working with qubits and performing quantum computing.

Computer readable program instructions are typically loaded onto computer 301 to cause a series of operational steps to be performed by processor set 310 of computer 301 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 321 and the other storage media discussed below. The program instructions, and associated data, are accessed by processor set 310 to control and direct performance of the inventive methods. In computing environment 300, at least some of the instructions for performing the inventive methods may be stored in block 100 in persistent storage 313.

COMMUNICATION FABRIC 311 is the signal conduction path that allows the various components of computer 301 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 312 is any type of volatile memory now known or to be developed in the future. Examples include dynamic type random access memory (RAM) or static type RAM. Typically, volatile memory 312 is characterized by random access, but this is not required unless affirmatively indicated. In computer 301, the volatile memory 312 is located in a single package and is internal to computer 301, but, alternatively or additionally, the volatile memory may be distributed over multiple packages and/or located externally with respect to computer 301.

PERSISTENT STORAGE 313 is any form of non-volatile storage for computers that is now known or to be developed in the future. The non-volatility of this storage means that the stored data is maintained regardless of whether power is being supplied to computer 301 and/or directly to persistent storage 313. Persistent storage 313 may be a read only memory (ROM), but typically at least a portion of the persistent storage allows writing of data, deletion of data and re-writing of data. Some familiar forms of persistent storage include magnetic disks and solid state storage devices.

Operating system 322 may take several forms, such as various known proprietary operating systems or open source Portable Operating System Interface-type operating systems that employ a kernel. The code included in block 100 typically includes at least some of the computer code involved in performing the inventive methods.

PERIPHERAL DEVICE SET 314 includes the set of peripheral devices of computer 301. Data communication connections between the peripheral devices and the other components of computer 301 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 323 may include components such as a display screen, speaker, microphone, wearable devices (such as goggles and smart watches), keyboard, mouse, printer, touchpad, game controllers, and haptic devices. Storage 324 is external storage, such as an external hard drive, or insertable storage, such as an SD card. Storage 324 may be persistent and/or volatile. In some embodiments, storage 324 may take the form of a quantum computing storage device for storing data in the form of qubits. In embodiments where computer 301 is required to have a large amount of storage (for example, where computer 301 locally stores and manages a large database) then this storage may be provided by peripheral storage devices designed for storing very large amounts of data, such as a storage area network (SAN) that is shared by multiple, geographically distributed computers. IoT sensor set 325 is made up of sensors that can be used in Internet of Things applications. For example, one sensor may be a thermometer and another sensor may be a motion detector.

NETWORK MODULE 315 is the collection of computer software, hardware, and firmware that allows computer 301 to communicate with other computers through WAN 302. Network module 315 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 315 are performed on the same physical hardware device. In other embodiments (for example, embodiments that utilize software-defined networking (SDN)), the control functions and the forwarding functions of network module 315 are performed on physically separate devices, such that the control functions manage several different network hardware devices. Computer readable program instructions for performing the inventive methods can typically be downloaded to computer 301 from an external computer or external storage device through a network adapter card or network interface included in network module 315.

WAN 302 is any wide area network (for example, the internet) capable of communicating computer data over non-local distances by any technology for communicating computer data, now known or to be developed in the future. In some embodiments, the WAN 302 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 303 is any computer system that is used and controlled by an end user (for example, a customer of an enterprise that operates computer 301), and may take any of the forms discussed above in connection with computer 301. EUD 303 typically receives helpful and useful data from the operations of computer 301. For example, in a hypothetical case where computer 301 is designed to provide a recommendation to an end user, this recommendation would typically be communicated from network module 315 of computer 301 through WAN 302 to EUD 303. In this way, EUD 303 can display, or otherwise present, the recommendation to an end user. In some embodiments, EUD 303 may be a client device, such as thin client, heavy client, mainframe computer, desktop computer and so on.

REMOTE SERVER 304 is any computer system that serves at least some data and/or functionality to computer 301. Remote server 304 may be controlled and used by the same entity that operates computer 301. Remote server 304 represents the machine(s) that collect and store helpful and useful data for use by other computers, such as computer 301. For example, in a hypothetical case where computer 301 is designed and programmed to provide a recommendation based on historical data, then this historical data may be provided to computer 301 from remote database 330 of remote server 304.

PUBLIC CLOUD 305 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 305 is performed by the computer hardware and/or software of cloud orchestration module 341. The computing resources provided by public cloud 305 are typically implemented by virtual computing environments that run on various computers making up the computers of host physical machine set 342, which is the universe of physical computers in and/or available to public cloud 305. The virtual computing environments (VCEs) typically take the form of virtual machines from virtual machine set 343 and/or containers from container set 344. It is understood that these VCEs may be stored as images and may be transferred among and between the various physical machine hosts, either as images or after instantiation of the VCE. Cloud orchestration module 341 manages the transfer and storage of images, deploys new instantiations of VCEs and manages active instantiations of VCE deployments. Gateway 340 is the collection of computer software, hardware, and firmware that allows public cloud 305 to communicate through WAN 302.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 306 is similar to public cloud 305, except that the computing resources are only available for use by a single enterprise. While private cloud 306 is depicted as being in communication with WAN 302, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 305 and private cloud 306 are both part of a larger hybrid cloud.

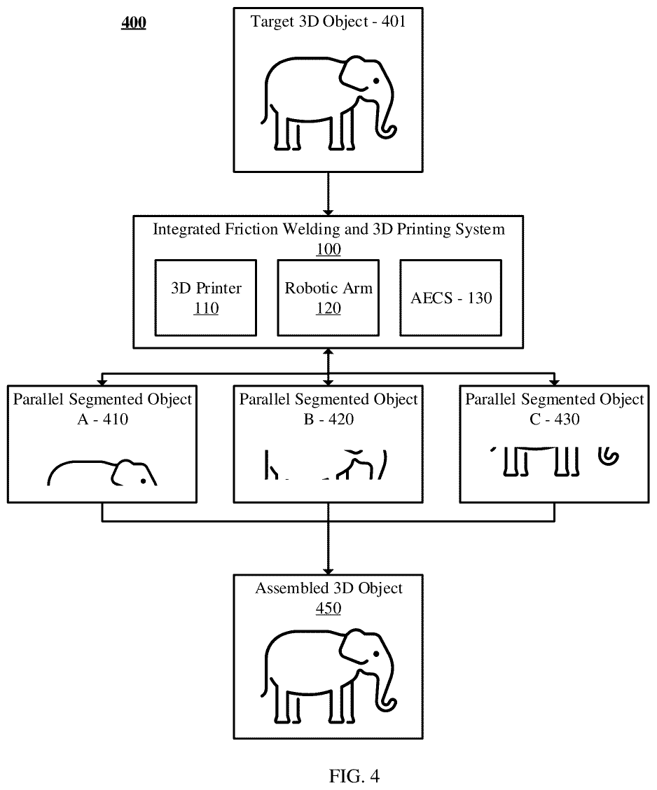

Referring now to FIG. 4, a block diagram showing a system that performs synchronized 3D printing and friction welding, in accordance with an embodiment of the present invention.

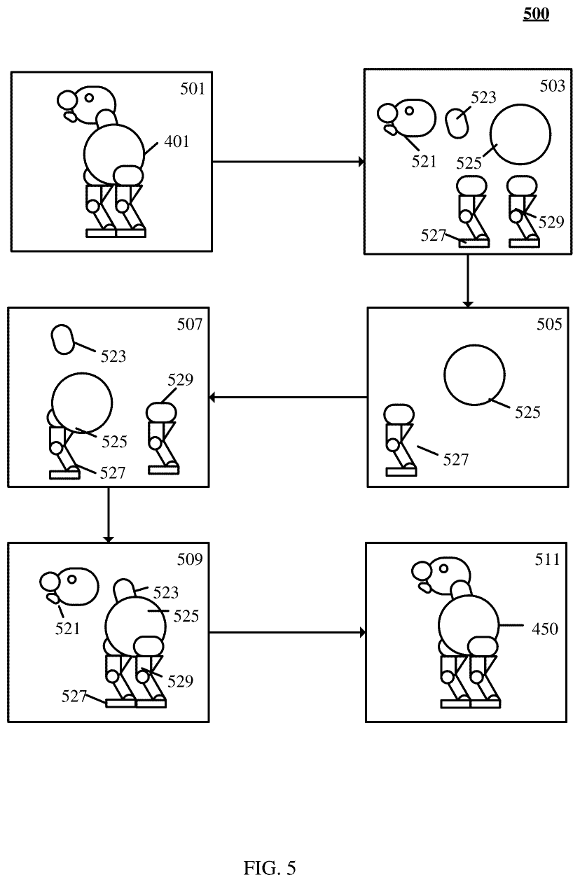

In system 400, a target 3D object 401 can be analyzed with an integrated friction welding and 3D printing system 100. The AECS 130 can analyze the target 3D object 401 and can identify segmentation points and assembly points to generate parallel segmentation object A 410, parallel segmentation object B 420, and parallel segmentation object C 430 that can be printed separately in parallel and assembled with friction welding. After the analysis, the AECS 130 can generate a synchronized printing plan that determines the order of the 3D printing process and the friction welding process. The parallel segmentation object A 410, parallel segmentation object B 420, and parallel segmentation object C 430 can be 3D printed in parallel and then friction welded together to generate the assembled 3D object 450. Depending on the parallel segmentation objects and the synchronized printing plan, the parallel segmentation objects can be 3D printed and friction welded in parallel, instead of sequential order. This is shown in further detail in FIG. 5.

The system 400 is not limited to 3D printing large objects such as the target 3D object described herein. The system 400 can be applied to other fields such as manufacturing custom-made consumer goods, generating prosthesis in the medical field, manufacturing large buildings, structures, structural tools, generating large component fabrication for aerospace engineering, vehicle frame generation for automotive manufacturing, hull construction for marine engineering, etc. In another embodiment, four-dimensional printing can be performed by utilizing morphing material in response to environmental stimulus.

Referring now to FIG. 5, a block diagram showing a method of synchronized 3D printing and friction welding, in accordance with an embodiment of the present invention.

In method 500, specifically in block 501, a target 3D object 401 can be processed by the present embodiments to assemble a large scale model as assembled 3D object 450.

In block 503, the target 3D object 502 can be processed to generate five determined parallel segmented objects, namely, parallel segmented object A 521, parallel segmented object B 523, parallel segmented object C 525, parallel segmented object D 527, and parallel segmented object E 529.

In block 505, parallel segmented object C 525 can be 3D printed first, then parallel segmented object D 527.

In block 507, while parallel segmented object E 529 is being 3D printed, parallel segmented object D 527 can be friction welded to parallel segmented object C 525. Additionally, while parallel segmented object E 529 is being 3D printed, parallel segmented object B 523 can be 3D printed.

In block 509, after parallel segmented object E 529 and parallel segmented object B 523 finish 3D printing, parallel segmented object E 529 and parallel segmented object B 523 can be friction welded to parallel segmented object C 525, and parallel segmented object A 521 can be 3D printed while the friction welding process for parallel segmented object E 529 and parallel segmented object B 523 is ongoing.

In block 511, after parallel segmented object A 521 finishes 3D printing, parallel segmented object A 521 can be friction welded to parallel segmented object B 523 to finish the process and produce the assembled 3D object 450.

The present embodiments can employ neural network 139 which is included in AECS 130.

An artificial neural network (ANN) is an information processing system that is inspired by biological nervous systems, such as the brain. One element of ANNs is the structure of the information processing system, which includes a large number of highly interconnected processing elements (called “neurons”) working in parallel to solve specific problems. ANNs are furthermore trained using a set of training data, with learning that involves adjustments to weights that exist between the neurons. An ANN is configured for a specific application, such as pattern recognition or data classification, through such a learning process.

ANNs demonstrate an ability to derive meaning from complicated or imprecise data and can be used to extract patterns and detect trends that are too complex to be detected by humans or other computer-based systems. The structure of a neural network is known generally to have input neurons that provide information to one or more “hidden” neurons. Connections between the input neurons and hidden neurons are weighted, and these weighted inputs are then processed by the hidden neurons according to some function in the hidden neurons. There can be any number of layers of hidden neurons, and as well as neurons that perform different functions. There exist different neural network structures as well, such as a convolutional neural network, a maxout network, etc., which may vary according to the structure and function of the hidden layers, as well as the pattern of weights between the layers. The individual layers may perform particular functions, and may include convolutional layers, pooling layers, fully connected layers, softmax layers, or any other appropriate type of neural network layer. Finally, a set of output neurons accepts and processes weighted input from the last set of hidden neurons.

This represents a “feed-forward” computation, where information propagates from input neurons to the output neurons. Upon completion of a feed-forward computation, the output is compared to a desired output available from training data. The error relative to the training data is then processed in “backpropagation” computation, where the hidden neurons and input neurons receive information regarding the error propagating backward from the output neurons. Once the backward error propagation has been completed, weight updates are performed, with the weighted connections being updated to account for the received error. It should be noted that the three modes of operation, feed forward, back propagation, and weight update, do not overlap with one another. This represents just one variety of ANN computation, and that any appropriate form of computation may be used instead.

To train an ANN, training data can be divided into a training set and a testing set. The training data includes pairs of an input and a known output. During training, the inputs of the training set are fed into the ANN using feed-forward propagation. After each input, the output of the ANN is compared to the respective known output. Discrepancies between the output of the ANN and the known output that is associated with that particular input are used to generate an error value, which may be backpropagated through the ANN, after which the weight values of the ANN may be updated. This process continues until the pairs in the training set are exhausted.

After the training has been completed, the ANN may be tested against the testing set, to ensure that the training has not resulted in overfitting. If the ANN can generalize to new inputs, beyond those which it was already trained on, then it is ready for use. If the ANN does not accurately reproduce the known outputs of the testing set, then additional training data may be needed, or hyperparameters of the ANN may need to be adjusted.

In an embodiment, the AECS 130 can be trained to determine optimal printing parameters 170 for the 3D printer 110 based on the historical data of past printing processes and how they affected the printing process of the target 3D object. In an embodiment, the AECS 130 can be trained to determine optimal welding parameters 168 for parallel segmented objects 176 and the robotic arm 120 based on the historical data of past welding processes and how they affected the welding process of the parallel segmented objects 176 to generate an assembled 3D object 450. The AECS 130 can be trained continuously using newly acquired data and feedback obtained from the network of sensors 140 or provided by a decision-making entity or a pretrained artificial intelligence model and by retaining previously learned knowledge using elastic weight consolidation (EWC).

ANNs may be implemented in software, hardware, or a combination of the two. For example, each weight may be characterized as a weight value that is stored in a computer memory, and the activation function of each neuron may be implemented by a computer processor. The weight value may store any appropriate data value, such as a real number, a binary value, or a value selected from a fixed number of possibilities, that is multiplied against the relevant neuron outputs. Alternatively, the weights may be implemented as resistive processing units (RPUs), generating a predictable current output when an input voltage is applied in accordance with a settable resistance.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Having described preferred embodiments of a system and method (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A computer system, comprising:
a processor set;
one or more computer-readable storage media; and
program instructions stored on the one or more computer-readable storage media to cause the processor set to perform operations comprising:
generating, with an artificial intelligence enabled control system (AECS), an initial printing plan that slices a target 3D object into parallel segmented objects;
simulating, with the AECS, a 3D printing process and a friction welding process for the initial printing plan of the parallel segmented objects to generate a synchronized printing plan;
printing the parallel segmented objects based on the synchronized printing plan by generating g-codes for a 3D printer; and
welding the parallel segmented objects based on the synchronized printing plan by generating instruction commands for a robotic arm.

2. The computer system of claim 1, further comprising a motion control system that synchronizes actions of the 3D printer and the robotic arm.

3. The computer system of claim 1, wherein the 3D printer that includes 3D digital model slicing system that generates G-code that accounts for the parallel segmented objects.

4. The computer system of claim 1, wherein the robotic arm further includes a gripper to securely hold the parallel segmented objects.

5. The computer system of claim 1, wherein the robotic arm further comprises a local calibration system that calibrates and aligns the robotic arm with the 3D printer to ensure precise coordinating during printing and friction welding.

6. The computer system of claim 1, further comprising a calibration system that includes a quality control system that identifies issues with an assembly of an assembled 3D object.

7. The computer system of claim 1, wherein the synchronization plan coordinates a sequence of actions of the 3D printer and the robotic arm based on the printing plan.

8. A computer-implemented method for synchronized three-dimensional (3D) printing and friction welding of objects, comprising:
generating, with an artificial intelligence (AI) enabled control system (AECS), an initial printing plan that slices a target 3D object into parallel segmented objects;
simulating, with the AECS, a 3D printing process and a friction welding process for the initial printing plan of the parallel segmented objects to generate a synchronized printing plan;
printing the parallel segmented objects based on the synchronized printing plan by generating g-codes for a 3D printer; and
welding the parallel segmented objects based on the synchronized printing plan by generating instruction commands for a robotic arm.

9. The computer-implemented method of claim 8, wherein generating the initial printing plan further comprises generating a granular mesh model of the target 3D object.

10. The computer-implemented method of claim 8, wherein generating the initial printing plan further comprises identifying assembly points of the target 3D object as candidates for friction welding based on shape constraints of the target 3D object.

11. The computer-implemented method of claim 10, wherein generating the initial printing plan further comprises determining segmentation points of the target 3D object that corresponds to the assembly points.

12. The computer-implemented method of claim 8, wherein printing the parallel segmented objects further comprises determining, with the AECS, optimal printing parameters of the 3D printer to print the parallel segmented objects based on the synchronized printing plan.

13. The computer-implemented method of claim 8, wherein welding the parallel segmented objects further comprises determining, with the AECS, optimal welding parameters of the robotic arm to weld the parallel segmented objects based on the synchronized printing plan.

14. The computer-implemented method of claim 8, further comprising learning, with the AECS, a specification of the target 3D object based on past data.

15. A computer program product for synchronized three-dimensional (3D) printing and friction welding of objects, the computer program product comprising one or more computer-readable storage media; and program instructions stored on the one or more computer-readable storage media to perform operations comprising:
generating, with an artificial intelligence (AI) enabled control system (AECS), an initial printing plan that slices a target 3D object into parallel segmented objects;
simulating, with the AECS, a 3D printing process and a friction welding process for the initial printing plan of the parallel segmented objects to generate a synchronized printing plan;
printing the parallel segmented objects based on the synchronized printing plan by generating g-codes for a 3D printer; and
welding the parallel segmented objects based on the synchronized printing plan by generating instruction commands for a robotic arm.

16. The computer program product of claim 15, wherein the operations of simulating the 3D printing process further comprises generating simulations of different orientations of the 3D printing and the friction welding process to determine an optimal orientation based on an optimality threshold.

17. The computer program product of claim 15, wherein the operations of simulating the 3D printing process further comprises generating simulations of synchronization of the 3D printing and friction welding to determine an order of both actions.

18. The computer program product of claim 15, wherein the operations of simulating the 3D printing process further comprises generating a synchronization printing plan where the 3D printing and friction welding are done in parallel for the parallel segmented objects.

19. The computer program product of claim 15, wherein the operations of printing the parallel segmented objects further comprises determining, with the AECS, optimal printing parameters of the 3D printer to print the parallel segmented objects based on the synchronized printing plan.

20. The computer program product of claim 15, wherein the operations of welding the parallel segmented objects further comprises determining, with the AECS, optimal welding parameters of the robotic arm to weld the parallel segmented objects based on the synchronized printing plan.
